(19) United States
(12) Patent Application Publication
(10) Pub. No.: US 2012/0140386 A1
(43) Pub. Date: Jun. 7, 2012

(54) CASING OF ELECTRONIC DEVICE

(75) Inventors: TING-TING ZHAO, Shenzhen City (CN); XIAO-HUI ZHOU, Shenzhen City (CN); MIN-LI LI, Shenzhen City (CN); HONG LI, Shenzhen City (CN)

(73) Assignees: HON HAI PRECISION IDUSTRY CO., LTD., Tu-Cheng (TW); HONG FU JIN PRECISIO INDUSTRY (SHENZHEN) CO., LTD., Shenzhen City (CN)

(21) Appl. No.: 13/186,689

(22) Filed: Jul. 20, 2011

(30) Foreign Application Priority Data
Dec. 4, 2010 (CN) 201010574514.X

(51) Int. Cl. H05K 5/00

(52) U.S. Cl. 361/679.01

(57) ABSTRACT

A casing of an electronic device includes a holder, a cover and a wire baffle structure. The holder includes a supporting post. The supporting post axially defines a mounting hole therethrough. The cover includes a fixing post corresponding to the supporting post. The fixing post axially defines a fixing hole therethrough. The fixing hole communicates with the mounting hole. The wire baffle structure is formed at a top end of the supporting post. The wire baffle structure encircles a free end of the fixing post.

### BACKGROUND

1. Technical Field

The present disclosure relates to electronic devices and, more particularly, to a casing of an electronic device.

2. Description of Related Art

A casing of an electronic device includes a holder and a cover engaged with the holder. The holder includes a supporting post, and the cover includes a fixing post corresponding to the supporting post. A fastener, such as a screw extends through the supporting post and the fixing post to fix the cover on the holder. However, electric wires in the electronic device are easily trapped between the supporting post and the fixing post. The electric wires will be abraded in assembly of the casing and a lifespan of the electronic device will be reduced.

Therefore, what is needed is a casing of an electronic device, which can overcome the above described shortcomings.

### BRIEF DESCRIPTION OF THE DRAWINGS

FIG. 1 is a disassembled view of a casing of an electronic device in accordance with an exemplary embodiment of the present disclosure.

FIG. 2 is an assembled cross-section of the casing of FIG. 1.

FIG. 3 is an enlarged view of III of FIG. 2.

FIG. 4 is an inverted view of a cover of the casing of FIG. 1.

### DETAILED DESCRIPTION

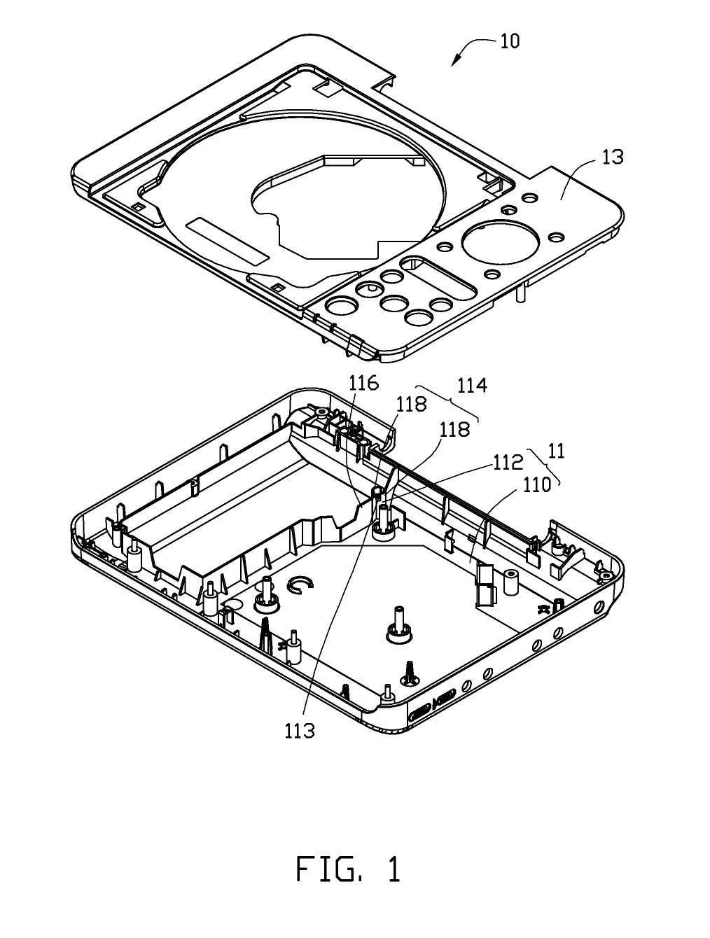

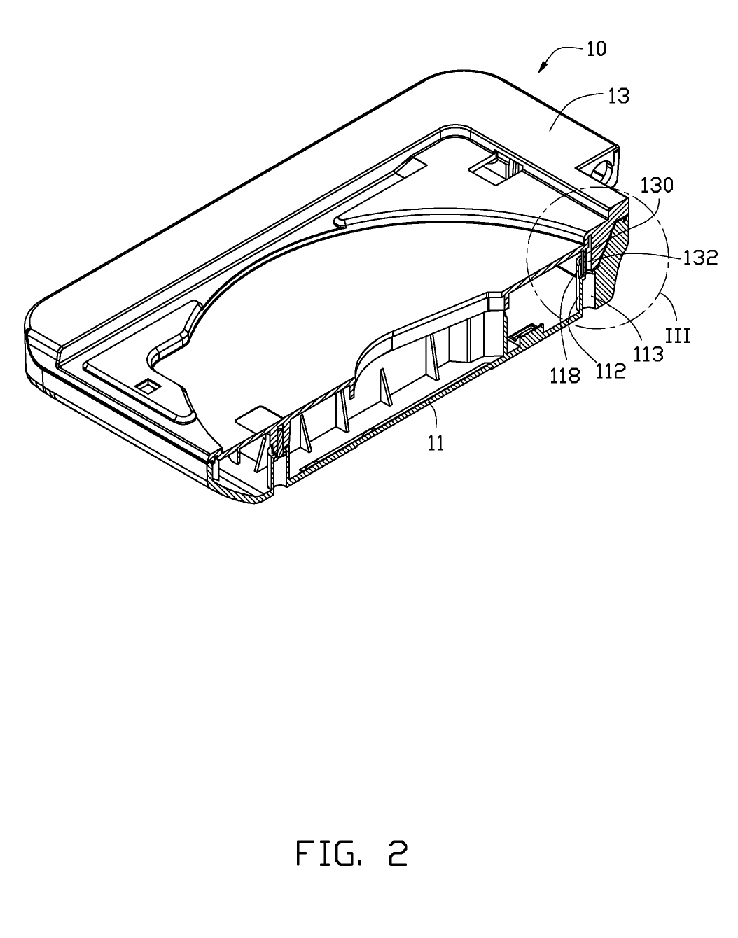

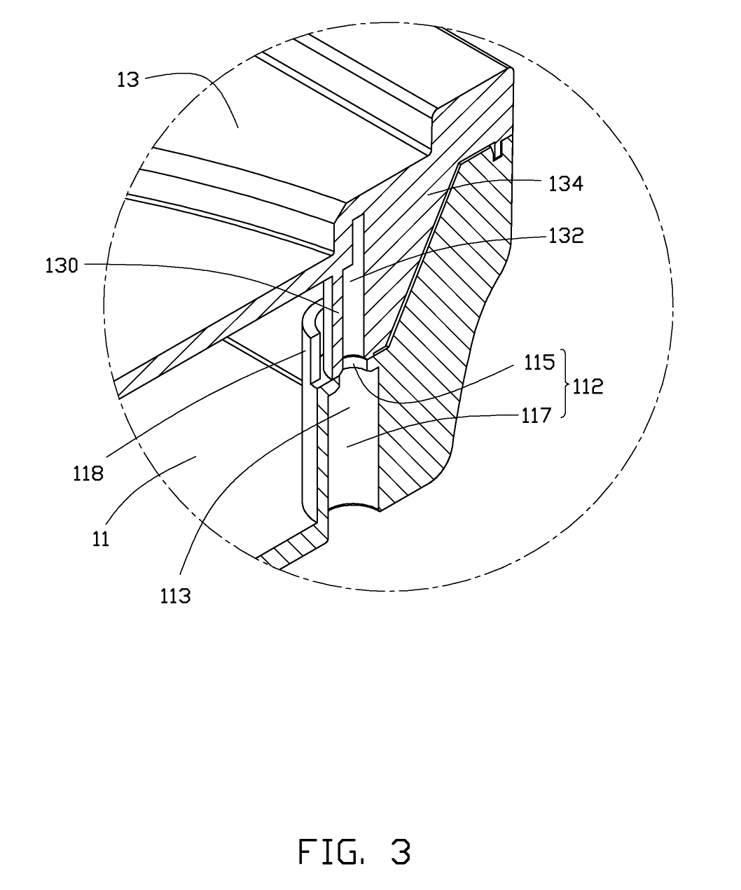

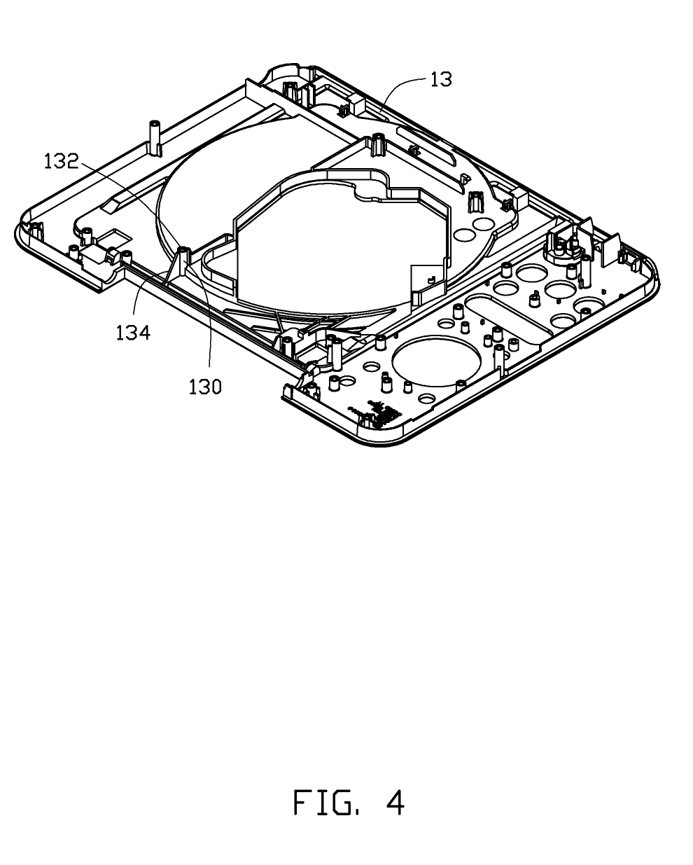

Referring to FIGS. 1 to 4, a casing 10 for an electronic device according to an exemplary embodiment of the present disclosure is shown. The electronic device can be, for example, a portable DVD player, a notebook computer or a projector. The casing 10 includes a holder 11 and a cover 13 engaged with the holder 11, thereby receiving and fixing electronic components of the electronic device therein.

The holder 11 includes a base 110 and a number of supporting posts 112integrally extending upward from the base 110. The base 110 and the supporting posts 112 are integrally formed as a single monolithic piece from plastic via injection molding. In other words, the base 110 and the supporting posts 112 are portions of a single body formed from the same material (i.e., plastic).

Each the supporting post 112 includes a hollow cylindrical second section 117 joined to the base 110 and a hollow disk-shaped first section 115 extending inwardly from a top end of the hollow cylindrical second section 117. The second section 117 has an interior diameter greater than that of the first section 115, and the second section 117 has an exterior diameter equal to that of the first section 115. In the present embodiment, the first section 115 and the second section 117 axially define a step-shaped mounting hole 113 therethrough. A first part of the mounting hole 113 corresponding to the first section 115 has a diameter less than that of a second part of the mounting hole 113 corresponding to the second section 117.

In the present embodiment, each the supporting post 112 further includes two reinforcing ribs 116 arranged at two opposite sides of the supporting post 112. The reinforcing ribs 116 are integrally formed with the base 110.

The cover 13 includes a number of fixing posts 130 corresponding to the supporting posts 112 respectively. Each the fixing post 130 axially defines a fixing hole 132 therethrough. A free end of the fixing post 130 is engaged with a top side of the first section 115 of one of the supporting posts 112. In the present embodiment, the exterior diameter of the first section 115 of the supporting post 112 is larger than that of the fixing post 130. The interior diameter of the first section 115 of the supporting post 112 is equal to the diameter of the fixing hole 132. The mounting hole 113 communicates with the fixing hole 132.

In the present embodiment, each the fixing post 130 further includes two reinforcing ribs 134 arranged at two opposite sides of the fixing post 130. The reinforcing ribs 134 are integrally formed with the cover 13.

A number of wire baffle structures 114 are respectively formed at the top end and an outer periphery of the supporting posts 112. Each the wire baffle structure 114 encircles the corresponding first section 115 of the supporting post 112. In the present embodiment, each the wire baffle structure 114 includes two tabs 118 opposite to each other. Each tab 118 is semi-annular in cross-section. The two tabs 118 cooperatively define an opening, and the opening has an interior diameter greater than that of the corresponding first section 115 of the supporting post 112, and the opening has an interior diameter greater than an exterior diameter of the corresponding fixing post 130. In alternative embodiments, the wire baffle structure 114 wire baffle structure can be a hollow cylinder, with an interior diameter greater than an exterior diameter of the fixing post 130.

In assembly of the casing 10, the cover 13 engages with the holder 11 to make the free end of the fixing post 130 abut against the top side of the first section 115 of the corresponding supporting post 112. The reinforcing ribs 134 are respectively arranged between the two tabs 118. The mounting hole 113 is aligned with the corresponding fixing hole 132. A fastener, such as a screw extends through the second section 117 and the first section 115 of the supporting post 112, and then inserts to the corresponding fixing hole 132 of the fixing post 130 to fix the cover 13 on the holder 11. In the embodiment, the head of the screw is received in the second section 117 of the supporting post 112.

The wire baffle structures 114 encircle the free end of the fixing posts 130 respectively preventing electric wires in the electronic device from wedging between the supporting posts 112 and the corresponding fixing posts 130 and being damaged. Additionally, the cover 13 can be assembled to the holder more easily.

It can be understood that, the casing 10 can be include only one supporting post 112, one fixing post 130 and one wire baffle structure 114.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A casing of an electronic device, the casing comprising:
a holder, the holder comprising a supporting post, the supporting post axially defining a mounting hole therethrough;
a cover, the cover comprising a fixing post corresponding to the supporting post, the fixing post axially defining a fixing hole therethrough, the fixing hole communicating with the mounting hole; and
a wire baffle structure, the wire baffle structure being formed at a top end of the supporting post, the wire baffle structure encircling a free end of the fixing post.

2. The casing of claim 1, wherein the wire baffle structure comprises two semi-annular tabs opposite to each other.

3. The casing of claim 1, wherein the wire baffle structure has a hollow cylindrical shape.

4. The casing of claim 1, wherein the supporting post comprises a first section at top end and a second section adjacent to the holder and away from the top end.

5. The casing of claim 4, wherein the second section has an interior diameter larger than that of the first section.

6. The casing of claim 5, wherein the mounting hole is a step-shaped.

7. The casing of claim 4, wherein the first section of the supporting post has an exterior diameter larger than that of the fixing post.

8. The casing of claim 4, wherein the first section of the supporting post has an interior diameter equal to that of the fixing hole.

9. The casing of claim 1, wherein the cover further comprises two reinforcing ribs arranged at opposite sides of the fixing post.

10. The casing of claim 1, wherein the holder further comprises two reinforcing ribs arranged at two opposite sides of the supporting post.

11. A casing of an electronic device, the casing comprising:
a holder, the holder comprising a number of supporting posts, each of the supporting posts axially defining a mounting hole therethrough;
a cover, the cover comprising a number of fixing posts corresponding to the supporting posts, each of the fixing post axially defining a fixing hole therethrough, the fixing hole communicating with the corresponding mounting hole; and
a number of wire baffle structures, each the wire baffle structure being formed between a top end of one of the supporting post and a free end of one of the fixing post, the wire baffle structure preventing wires from wedging between the supporting post and the corresponding fixing post.

12. The casing of claim 11, wherein each the wire baffle structure is formed at the top end and an outer periphery of the supporting post.

13. The casing of claim 11, wherein each the wire baffle structure comprises a hollow cylindrical.

14. The casing of claim 11, wherein each the supporting post comprises a first section at top end and a second section adjacent to the first section and away from the top end, and the second section has an interior diameter larger than that of the first section.

15. The casing of claim 14, wherein the first section of the supporting post has an interior diameter equal to that of the fixing hole.
